(19) United States
(12) Patent Application Publication
(10) Pub. No.: US 2025/0285859 A1
(43) Pub. Date: Sep. 11, 2025

(54) METHOD FOR MANUFACTURING GROUP 3 NITRIDE SEMICONDUCTOR TEMPLATE

(71) Applicant: WAVELORD CO., LTD, Hwaseong-si (KR)

(72) Inventors: Juneo SONG, Suwon-si (KR); Hyeong Seon YUN, Paju-si (KR); Young Hun HAN, Osan-si (KR); Ji Hyung MOON, Gunpo-si (KR)

(73) Assignee: WAVELORD CO., LTD, Hwaseong-si (KR)

(21) Appl. No.: 18/860,654

(22) PCT Filed: Nov. 2, 2023
(86) PCT No.: PCT/KR2023/017365

§ 371 Date: Oct. 27, 2024

(30) Foreign Application Priority Data
Nov. 9, 2022 (KR) 10-2022-0148587

(51) Int. Cl. H01L 21/02; C30B 25/18; C30B 29/40; C30B 33/00

(52) U.S. Cl. CPC H01L 21/0254; C30B 25/183; C30B 25/186; C30B 29/403; C30B 33/00; H01L 21/02381; H01L 21/0242; H01L 21/02488

(57) ABSTRACT

The present invention relates to a method for manufacturing a group 3 nitride semiconductor template, the method comprising: a growing step of growing a seed layer with a nitrogen polar surface as an upper surface on a growth substrate; a depositing step of depositing a protective layer on the seed layer; a bonding step of bonding the protective layer and a support substrate through a bonding layer; and a removing step of removing the growing substrate to expose a metal polar surface of the seed layer.

### TECHNICAL FIELD

The present invention relates to a method of manufacturing a group III nitride semiconductor template.

### BACKGROUND ART

Unlike SiC semiconductor devices that are grown, designed, and manufactured on the conventional homogeneous single-crystalline SiC growth substrate (wafer), group III nitride semiconductor devices are designed and manufactured by epitaxially growing a group III nitride semiconductor directly on a heterogeneous large-diameter (6 inches or larger) single-crystalline sapphire, SiC, or Si growth substrate due to the absence of low-cost commercial single-crystalline GaN and AlN growth substrates, and due to a difference in lattice constant (LC) with the growth substrate, various high-density crystallographic defects occur, which degrades the performance and quality of the semiconductor device, making it very difficult to expand the scope of application.

Specifically, in a technique of epitaxially growing a group III nitride semiconductor directly on a heterogeneous large-diameter single-crystalline sapphire, SiC, or Si growth substrate, three factors such as a surface temperature difference (ΔT) between upper and lower portions of the growth substrate, an LC difference (Δa), and a coefficient of thermal expansion difference (Δα) induce stress in the group III nitride epitaxy in a stepwise manner, resulting in crystallographic defects, concave or convex bowing, etc.

Due to the above-described three stress influencing factors, the following problems occur when group III nitride material-based device products are manufactured.

First, when micro light emitting diode (LED) devices are grown, the epitaxy wafer bowing phenomenon occurs due to the above-described three stress influencing factors, and thus a surface temperature difference between the center and edge regions causes non-uniformity of an indium (In) composition ratio during the growth of an InGaN-based active layer (multi quantum wells (MQWs)), which greatly disperses the wavelength and photoelectric characteristics (operating voltage, optical output) in the wafer and significantly affects the yield of good products, resulting in increased manufacturing costs. In addition, the wafer bowing phenomenon lowers the uniformity of the aluminum (Al) composition ratio and the doping amount of magnesium (Mg) that is a p-type dopant atom in the p-type AlGaN that serves as an electron blocking layer that is continuously subsequently grown during the growth of micro LED devices with the InGaN-based active layer (MQWs), resulting in the issue of dispersion of the photoelectric characteristics in the wafer.

In addition, even when a power semiconductor device is grown, the above three stress influencing factors cause the epitaxy wafer bowing phenomenon, and thus there is a problem that the uniformity of the thickness and aluminum (Al) composition ratio of the AlGaN barrier with a thickness of about 20 nm in a high electron mobility transistor (HEMT) with a horizontal channel structure is degraded, tensile stress further becomes severe during the growth of a thick GaN of 10 μm or more for a power semiconductor device with a vertical drift structure, thereby causing quality degradation, and wafer bowing becomes severe during wafer cooling to room temperature after growth, thereby increasing the possibility of cracks.

In addition, even during the growth of a communication filter device, such as bulk acoustic wave (BAW) or surface acoustic wave (SAW) filters, made of AlN materials, in a filter device in which the crystallinity and thickness uniformity of AlN with high piezoelectricity significantly affect quality, there is a problem that the above three stress influencing factors cause the epitaxy wafer bowing phenomenon, and there is a problem that many cracks and quality degradation occur inside AlN around 500 nm due to strong tensile stress during the growth of AlN.

### DISCLOSURE

### Technical Problem

The present invention is intended to solve the above-described conventional problems and is directed to providing a method of manufacturing a group III nitride semiconductor template, which may manufacture a high-quality group III nitride semiconductor device by growing a group III nitride semiconductor seed layer having a nitrogen polar surface on an initial growth substrate and transferring the group III nitride semiconductor seed layer onto a final support substrate having high heat resistance and high corrosion resistance to have an indium (In), gallium (Ga), or aluminum (Al) metal polar surface.

### Technical Solution

According to the present invention, the above object is achieved by a method of manufacturing a group III nitride semiconductor template, which includes a growing operation of growing a seed layer whose upper surface is a nitrogen polar surface on a growth substrate, a depositing operation of depositing a protective layer on the seed layer, a bonding operation of bonding the protective layer to a support substrate through a bonding layer, and a removing operation of removing the growth substrate to expose a metal polar surface of the seed layer.

In addition, the growth substrate may be a silicon (Si) substrate.

In addition, the growing operation may include performing high-temperature heat treatment on the growth substrate in a hydrogen atmosphere, performing high-temperature nitriding treatment on a surface of the growth substrate in an ammonia atmosphere to form an SiN layer, depositing a buffer layer on the SiN layer, growing a compressive stress introduction layer on the buffer layer, and growing a seed layer having a nitrogen polar surface on the compressive stress introduction layer.

In addition, the removing operation may include removing the growth substrate, the SiN layer, the buffer layer, and the compressive stress introduction layer to expose the metal polar surface of the seed layer.

In addition, Mg doping or carrier gas modulation may be performed on at least one of the compressive stress introduction layer and the seed layer during growth.

In addition, the removing operation may include removing the growth substrate, the SiN layer, the buffer layer, the compressive stress introduction layer, and a region of the seed layer on which the Mg doping or carrier gas modulation is performed to expose the metal polar surface of the seed layer.

In addition, the growth substrate may be a sapphire (Al2O3) substrate.

In addition, the growing operation may include a first operation of performing high-temperature heat treatment on the growth substrate in a hydrogen atmosphere, a second operation of performing high-temperature nitriding treatment on a surface of the growth substrate in an ammonia atmosphere to form an AlN layer, a third operation of depositing a buffer layer on the AlN layer, and a fourth operation of growing a seed layer having a nitrogen polar surface on the buffer layer.

In addition, the removing operation may include removing the growth substrate, the AlN layer, and the buffer layer to expose the metal polar surface of the seed layer.

In addition, Mg doping or carrier gas modulation may be performed on the seed layer during growth.

In addition, the removing operation may include removing the growth substrate, the AlN layer, the buffer layer, and a region of the seed layer on which the Mg doping or carrier gas modulation is performed to expose the metal polar surface of the seed layer.

In addition, the depositing operation may include forming a reinforcement layer, which increases bonding strength and induces compressive stress, on the seed layer and then depositing the protective layer on the reinforcement layer.

In addition, the bonding operation may include forming a reinforcement layer, which increases bonding strength and induces compressive stress, on the support substrate and then bonding the protective layer to the reinforcement layer through a bonding layer.

In addition, the method according to the present invention may further include a re-growing operation of re-growing an device active layer on the exposed seed layer.

### Advantageous Effects

According to the present invention, since a homogeneous seed layer without a lattice constant difference can be formed on a final support substrate having high heat resistance and high corrosion resistance through dielectric bonding and epitaxy transfer processes, it is possible to significantly improve the performance and quality of a group III nitride semiconductor device grown on the seed layer.

In addition, according to the present invention, since the method can use not only single crystalline but also a polycrystalline microstructure resulting from a high-temperature sintering process and can also be applied to a wafer having a size of 8 inches or more, it is possible to secure cost competitiveness.

Meanwhile, the effects of the present invention are not limited to the above-described effects, and may include various effects within a range that is apparent to those skilled in the art from the following descriptions.

### DESCRIPTION OF DRAWINGS

FIG. 1 is a flowchart of a method of manufacturing a group III nitride semiconductor template according to a first embodiment of the present invention.

FIG. 2 shows a process of manufacturing a group III nitride semiconductor template according to the first embodiment of the present invention.

FIGS. 3 and 4 show that a seed layer whose upper surface is a nitrogen polar surface is grown through a growing operation of the method of manufacturing a group III nitride semiconductor template according to the first embodiment of the present invention.

FIG. 5 is a flowchart of a method of manufacturing a group III nitride semiconductor template according to a second embodiment of the present invention.

FIG. 6 shows a process of manufacturing a group III nitride semiconductor template according to the second embodiment of the present invention.

FIGS. 7 and 8 show that a seed layer whose upper surface is a nitrogen polar surface is grown through a growing operation of the method of manufacturing a group III nitride semiconductor template according to the second embodiment of the present invention.

FIG. 9 shows that an device active layer is re-grown on the seed layer of the group III nitride semiconductor template according to the method of manufacturing a group III nitride semiconductor template according to the first or second embodiment of the present invention.

### MODES OF THE INVENTION

Hereinafter, some embodiments of the present invention will be described in detail with reference to exemplary drawings. In adding reference numerals to components in each drawing, it should be noted that the same components have the same reference numerals as much as possible even when they are illustrated in different drawings.

In addition, in describing embodiments of the present invention, detailed descriptions of related known configurations or functions will be omitted when it is determined that the detailed descriptions obscure the understanding of the embodiments of the present invention.

In addition, terms such as first, second, A, B, (a), and (b) may be used to describe components of the embodiments of the present invention. These terms are only for the purpose of distinguishing one component from another component, and the nature, sequence, order, or the like of the corresponding component is not limited by the terms.

Group III nitride semiconductor devices are designed and manufactured by epitaxially growing a group III nitride semiconductor directly on a heterogeneous single-crystalline substrate wafer due to the absence of low-cost commercial single-crystalline GaN and AlN growth substrates, and due to a difference in lattice constant (LC) with an initial growth substrate, various high-density crystallographic defects occur, which degrades the performance and quality of the semiconductor device, making it very difficult to expand the scope of application.

The present invention is intended to solve such a problem and to minimize defects when a group III nitride semiconductor is grown by forming a homogeneous growth seed layer having an LC difference of zero on a final support substrate having high heat resistance and high corrosion resistance through dielectric wafer bonding and epitaxy transfer processes, thereby significantly improving the performance and quality of a group III nitride semiconductor device. However, when the growth seed layer is transferred onto the final support substrate, an exposed surface of the growth seed layer has a nitrogen polar surface, making it very difficult to grow another high-quality group III nitride semiconductor thereon.

Therefore, the present invention is characterized in that the growth seed layer is first grown to have a nitrogen polar surface on the initial growth substrate through processes of controlling crystallographic face and orientation angle, performing high- temperature surface nitriding treatment before growth, growing a buffer layer or nucleation layer, etc., and then the surface of the growth seed layer transferred onto the final support substrate has a metal (Ga, Al, In) polar surface through the dielectric bonding and epitaxy transfer processes.

A method S100 of manufacturing a group III nitride semiconductor template according to the first embodiment of the present invention will now be described in detail with reference to the accompanying drawings.

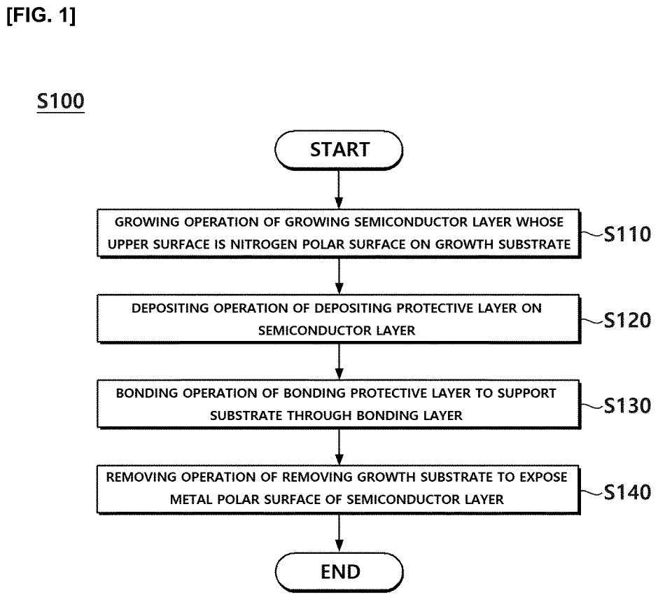

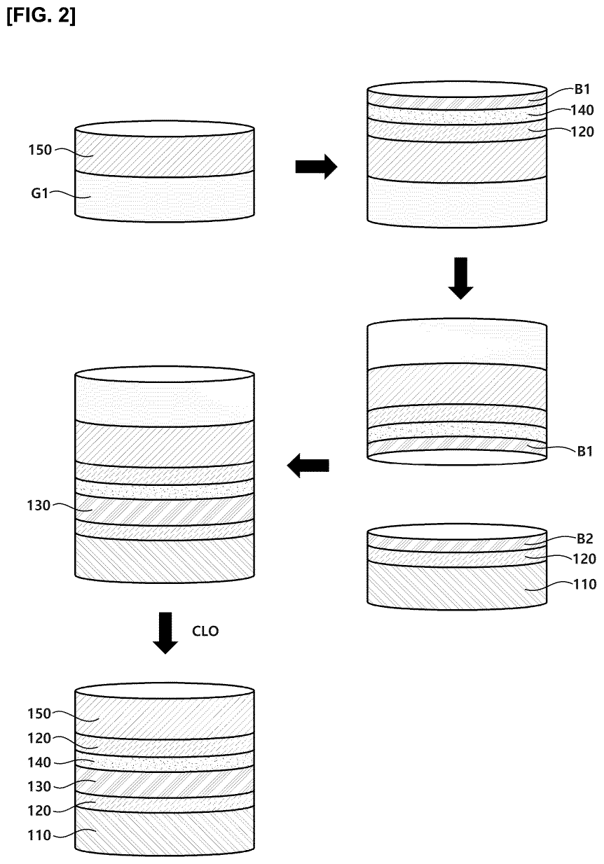

FIG. 1 is a flowchart of a method S100 of manufacturing a group III nitride semiconductor template according to the first embodiment of the present invention, and FIG. 2 shows a process of manufacturing a group III nitride semiconductor template according to the first embodiment of the present invention.

As shown in FIGS. 1 and 2, the method S100 of manufacturing a group III nitride semiconductor template according to the first embodiment of the present invention includes a growing operation S110, a depositing operation S120, a bonding operation S130, and a removing operation S140.

The growing operation S110 is an operation of growing a single-layer or multilayered group III nitride semiconductor seed layer 150 whose upper surface is a nitrogen polar surface on an initial growth substrate G1.

In the present embodiment, the initial growth substrate G1 may be removed by wet etching during a chemical lift off (CLO) process in the removing operation S140 to be described below and is provided as an Si growth substrate G1 that may be mechanically polished and selectively etched, and the Si growth substrate G1 is preferably made of Si having a (111) crystal face or (100) crystal face so that a high-quality group III nitride semiconductor seed layer 150 may be grown.

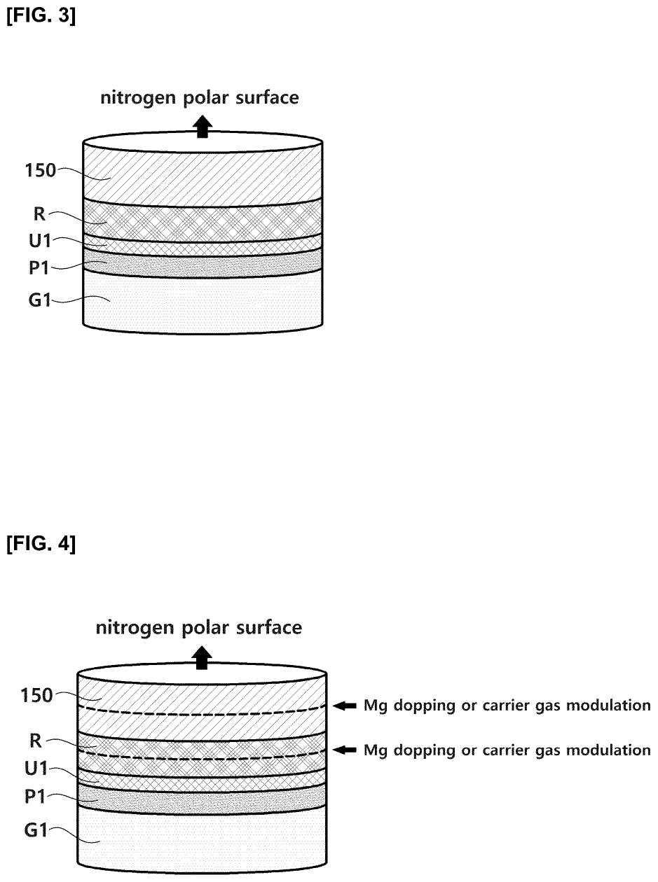

FIGS. 3 and 4 show that the seed layer 150 whose upper surface is a nitrogen polar surface is grown through the growing operation S110 of the method S100 of manufacturing a group III nitride semiconductor template according to the first embodiment of the present invention.

More specifically, the growing operation S110 includes preparing an initial growth substrate G1 on which a chemical mechanical polishing (CMP) process is performed, performing heat treatment on the initial growth substrate G1 at a high temperature of 1000° C. or higher in a hydrogen atmosphere (H2), performing nitriding treatment on a surface of the growth substrate G1 at a high temperature of 1000° C. or higher in an ammonia atmosphere (NH3 and N2) to form an SiN layer P1 having a film or island shape in a thickness of less than 5 nm, depositing an AlN buffer layer U1 (or a nucleation layer) on the SiN layer P1 in a thickness of 50 nm or less at a high temperature of 850° C. or higher, growing a AlxGayN (x<y) compressive stress introduction layer R for inducing compressive stress on the buffer layer U1 in a thickness of 500 nm or less at a high temperature of 950° C. or higher, and growing a seed layer 150 to have a thickness of 2 μm or less on the compressive stress introduction layer R.

As shown in FIG. 3, according to the growing operation S110, a structure in which the SiN layer P1, the AlN buffer layer U1, the AlxGayN (x<y) compressive stress introduction layer R, and the seed layer 150 are sequentially stacked is formed on the growth substrate G1, and through the SiN layer P1 and the buffer layer U1 according to high-temperature nitriding treatment, an AlxGayN (x<y) compressive stress introduction layer R having a nitrogen polar surface may be grown, and then a seed layer 150 having a nitrogen polar surface may be grown.

Meanwhile, as shown in FIG. 4, to reinforce the nitrogen polarity of the surface of the seed layer 150, Mg doping or carrier gas modulation may be performed on at least one of the compressive stress introduction layer R and the seed layer 150 during growth, and preferably, Mg doping or carrier gas modulation may be performed on each of the compressive stress introduction layer R and the seed layer 150 during growth.

Meanwhile, a channel through which gas generated during the process may move may be formed inside the seed layer 150 through an intentional patterning design.

The depositing operation S120 is an operation of depositing a protective layer 140 on the seed layer 150.

Here, the protective layer 140 is a layer for preventing the seed layer 150 from being damaged during a subsequent process, and may contain an oxide including SiO2 and a nitride including SiNx, and contain a metal, an alloy, etc.

Meanwhile, the depositing operation S120 may include, before depositing the protective layer 140, forming a reinforcement layer 120 on the seed layer 150 and then depositing the protective layer 140 on the reinforcement layer 120.

The bonding operation S130 is an operation of bonding the protective layer 140 to a support substrate 110 through a bonding layer 130.

In the present embodiment, the final support substrate 110 may be made of a material having high heat resistance or high corrosion resistance at a high temperature of 1000° C. or higher and in a reducing atmosphere and specifically, may contain AlNcera (heat dissipation performance: 170 to 230 W/mK), SiC (heat dissipation performance: 300 to 450 W/mK), Si (heat dissipation performance: 149 W/mK), sapphire (heat dissipation performance: 30 W/mK), and SiNx (heat dissipation performance: 90 W/mK). That is, in the present invention, not only a single crystalline but also a polycrystalline microstructure resulting from a high-temperature sintering process may be used, thereby securing cost competitiveness.

The bonding operation S130 may include bonding the final support substrate 110 to the protective layer 140 through the bonding layer 130 and specifically, may include forming a first bonding layer B1 on the protective layer 140, forming a second bonding layer B2 on the final support substrate 110, then pressing and bonding the first bonding layer B1 to the second bonding layer B2 at 200° C. or lower to form the bonding layer 130, and bonding the initial growth substrate G1 on which the protective layer 140 is formed to the final support substrate 110. In general, the greater the difference in coefficient of thermal expansion between the Si growth substrate G1 and the final support substrate 110 material, the more preferable it is to decrease the temperature of the bonding operation S130 to room temperature and increase the pressure, and it is preferable to perform a CMP process on each of the first bonding layer B1 and the second bonding layer B2 to increase bonding strength.

The bonding layer 130 (including the first bonding layer B1 and the second bonding layer B2) may be formed as a single layer or multiple layers, and a dielectric material whose properties do not change and has excellent thermal conductivity in a metal organic chemical vapor deposition (MOCVD) chamber (at a temperature of 1000° C. or higher and in a reducing atmosphere) in which a group III nitride semiconductor is grown is preferentially selected, and for example, SiO2, SiNx, SiCN, AlN, Al2O3, a-Si (amorphous silicon), and furthermore, a flowable oxide (FOx) such as spin on glass (SOG, liquid SiO2) or hydrogen silsesquioxane (HSQ) may be selected to decrease surface roughness.

Meanwhile, a channel through which gas generated during the process may move may be formed inside at least one of the first bonding layer B1 and the second bonding layer B2 through an intentional patterning design.

When wafer bonding is performed using a dielectric material, the dielectric material is sensitive to the roughness of the wafer bonding surface and wafer bowing, but the above-described patterning inside the bonding layer 130 can significantly decrease the issue of severe wafer surface roughness and bowing. In addition, the above-described patterning inside the bonding layer 130 can effectively prevent the formation of voids inside the bonding layer 130 and can also buffer minor thermal induced stress in addition to increasing bonding strength.

In the past, epitaxial wafer bowing may occur due to the thermo-mechanical induced stress caused by differences in LC and coefficient of thermal expansion (CTE) between the initial growth substrate G1 and the group III nitride semiconductor, but in the present invention, the above problem can be solved by strongly bonding the final support substrate 110 through the bonding layer 130. That is, since the epitaxial wafer to which the final support substrate 110 is bonded is in a stress-relieved state and wafer bowing can be minimized to almost zero, there is an advantage that the method can be applied to wafers having sizes of not only 4 inches, 6 inches, and 8 inches, but also 12 inches or more.

Meanwhile, the bonding operation S130 may include forming the reinforcement layer 120 on the support substrate 110 and then bonding the protective layer 140 to the reinforcement layer 120 through the bonding layer 130.

Here, the reinforcement layer 120 is a layer for increasing the bonding strength with the final support substrate 110 and inducing compressive stress, and more specifically, the reinforcement layer 120 may include a bonding reinforcement layer and a compressive stress layer.

The bonding reinforcement layer is a layer introduced to increase bonding strength when the protective layer 140 is bonded onto the final support substrate 110 through the bonding layer 130 and is formed on the seed layer 150 or the final support substrate 110, and it is preferable that a material constituting the bonding reinforcement layer be preferentially selected from SiO2, SiNx, etc.

The compressive stress layer is a layer that induces compressive stress and is formed on the bonding reinforcement layer, and the protective layer 140 or the second bonding layer B2 is formed on the compressive stress layer The compressive stress layer is made of a dielectric material with a greater CTE than the CTE of the final support substrate 110, for example, a material that relieves tensile stress, that is, induces compressive stress, such as AlN (4.6 ppm), AlNO (4.6 to 6.8 ppm), Al2O3 (6.8 ppm), SiC (4.8 ppm), SiCN (3.8 to 4.8 ppm), GaN (5.6 ppm), or GaNO (5.6 to 6.8 ppm), which serves to guide the quality improvement of products through stress control.

In the present invention, the above-described bonding reinforcement layer or compressive stress layer may be omitted in some cases, and in some cases, the entire reinforcement layer 120 may be omitted so that one surface of the seed layer 150 is in direct contact with the protective layer 140 or the final support substrate 110 is in direct contact with the second bonding layer B2. This case may be a structure that induces compressive stress together with a bonding function by depositing a material having a greater CTE than the final support substrate 110 on the protective layer 140 or the bonding layer 130.

Meanwhile, before depositing the reinforcement layer 120, a surface planarization layer may be introduced on the support substrate 110, and the surface planarization layer may be formed through a flowable oxide (FOx) such as SOG (liquid SiO2) or HSQ.

The removing operation S140 is an operation of removing the initial growth substrate G1 to expose the metal polar surface of the seed layer 150.

The removing operation S140 includes performing mechanical polishing (grinding and lapping) on a back surface of the Si growth substrate G1 and then removing the remaining thin Si growth substrate G1 using a CLO process, and specifically, includes completely removing the remaining thin Si growth substrate G1 through wet etching using a tetramethylammonium hydroxide (TMAH) or hydrofluoric+nitric+acetic acids (HNA) solution.

In this case, the removing operation S140 includes etching and removing all of the SiN layer P1, the buffer layer U1, and the compressive stress introduction layer R that are formed in the growing operation S110 as well as the growth substrate G1 to expose the metal polar surface of the seed layer 150 transferred onto the final support substrate 110 and additionally etching and removing a region of the seed layer 150 on which Mg doping or carrier gas modulation is performed when Mg doping or carrier gas modulation is performed on the seed layer 150 to expose the metal polar surface of the seed layer 150 transferred onto the final support substrate 110.

The group III nitride semiconductor template according to the present invention manufactured through the above-described process may basically have a structure in which the support substrate 110, the bonding layer 130, and the seed layer 150 are sequentially stacked, and the device active layer 160 made of a high-quality group III nitride semiconductor may be grown on the seed layer 150 transferred onto the final support substrate 110 and having the exposed metal polar surface.

Meanwhile, in some cases, the remaining thin Si growth substrate G1 after mechanical polishing may be removed through a plasma dry process such as SF6 to be completely removed, and heat treatment may be performed at a high temperature of 400° C. or higher to increase the bonding strength of the bonding layer 130 after mechanical polishing or after completely removing the remaining thin Si growth substrate G1.

FIG. 9 shows that the device active layer 160 is re-grown on the seed layer 150 of the group III nitride semiconductor template according to the method of manufacturing a group III nitride semiconductor template according to the first or second embodiment of the present invention.

After the group III nitride semiconductor template is manufactured through the above-described operations, the method according to the present invention may further include a re-growing operation, and as shown in FIG. 9, the re-growing operation is an operation of re-growing the device active layer 160 on the seed layer 150 having the exposed metal polar surface.

When the device active layer 160 for a micro LED device for a display or a UV LED device having a vertical chip structure is re-grown, the material of the seed layer 150 of the group III nitride semiconductor template according to the present invention may include GaN, InGaN, or AlN, and the material of the final support substrate 110 may include optically transparent sapphire (using a laser lift off (LLO) process) or AlNcera (using a CLO process) having the same CTE as the group III nitride.

In addition, when the device active layer 160 for a high-frequency and switching power semiconductor device is re-grown, the material of the seed layer 150 of the group III nitride semiconductor template according to the present invention may include GaN or AlN, and the material of the final support substrate 110 may include AlNcera (using a CLO process) having the same CTE as the group III nitride, SiC having high heat dissipation performance and a small difference in CTE from the group III nitride, or Si that enables the manufacturing of large-diameter wafers and has high cost-effectiveness.

In addition, when the device active layer 160 for an AlN BAW or SAW filter device for 5G or Wi-Fi communication is re-grown, the material of the seed layer 150 of the group III nitride semiconductor template according to the present invention may include AlN, and the material of the final support substrate 110 may include AlNcera (using a CLO process) having the same CTE as the group III nitride, SiC having high heat dissipation performance and having a small difference in CTE from the group III nitride, or optically transparent sapphire (using an LLO process).

Hereinafter, a method S200 of manufacturing the group III nitride semiconductor template according to the second embodiment of the present invention will be described in detail with reference to the accompanying drawings.

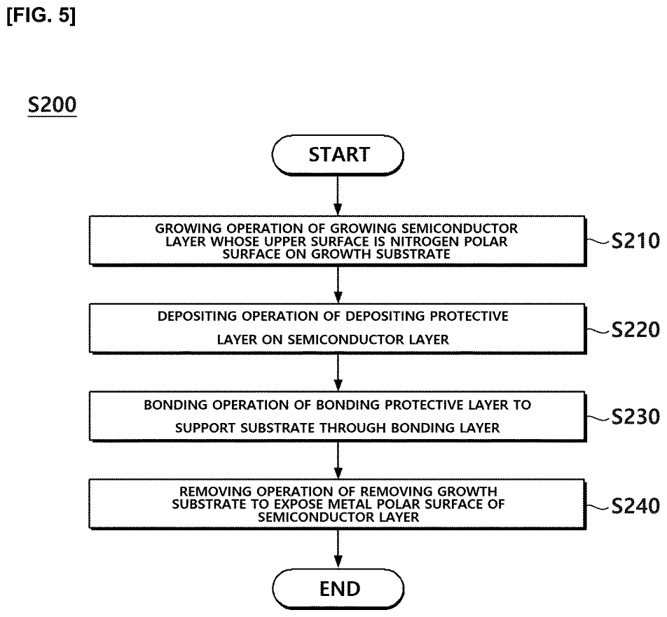

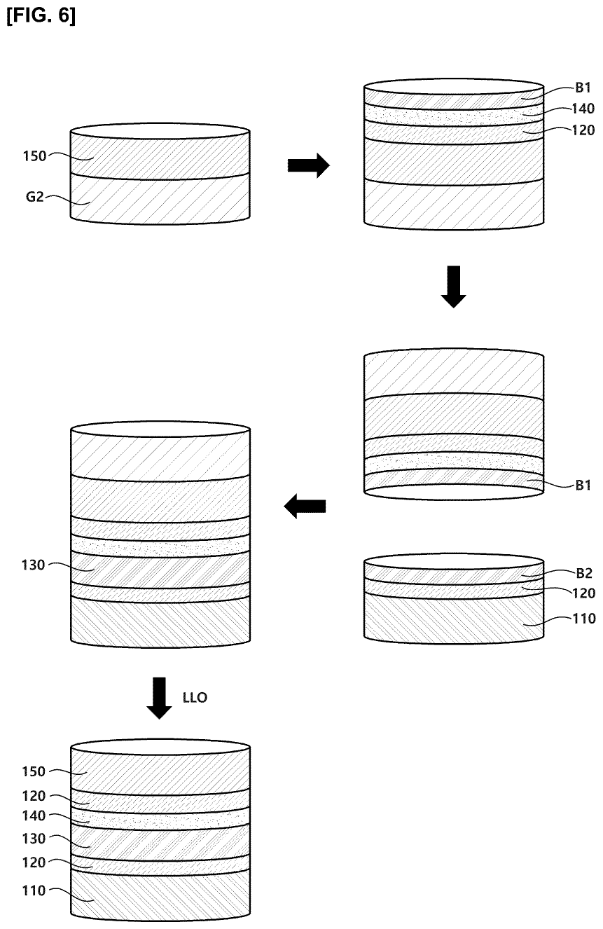

FIG. 5 is a flowchart of the method S200 of manufacturing a group III nitride semiconductor template according to the second embodiment of the present invention, and FIG. 6 shows a process of manufacturing a group III nitride semiconductor template according to the second embodiment of the present invention.

As shown in FIGS. 5 and 6, the method S200 of manufacturing a group III nitride semiconductor template according to the second embodiment of the present invention includes a growing operation S210, a depositing operation S220, a bonding operation S230, and a removing operation S240.

The growing operation S210 is an operation of growing a single-layer or multilayered group III nitride semiconductor seed layer 150 whose upper surface is a nitrogen polar surface on an initial growth substrate G2.

In the present embodiment, the initial growth substrate G2 may be provided as a sapphire (α-phase Al2O3) substrate that may theoretically transmit 100% of a laser beam (single wavelength light) without absorption in the LLO process of the removing operation S240 to be described below and which is optically transparent and has high-temperature heat resistance. In addition, the initial growth substrate G2 may be provided as a patterned sapphire substrate (PSS) having a protrusion shape that is patterned regularly or irregularly in various dimensions (size and shape) in microscale or nanoscale to minimize crystal defects inside the group III nitride semiconductor thin film grown thereon.

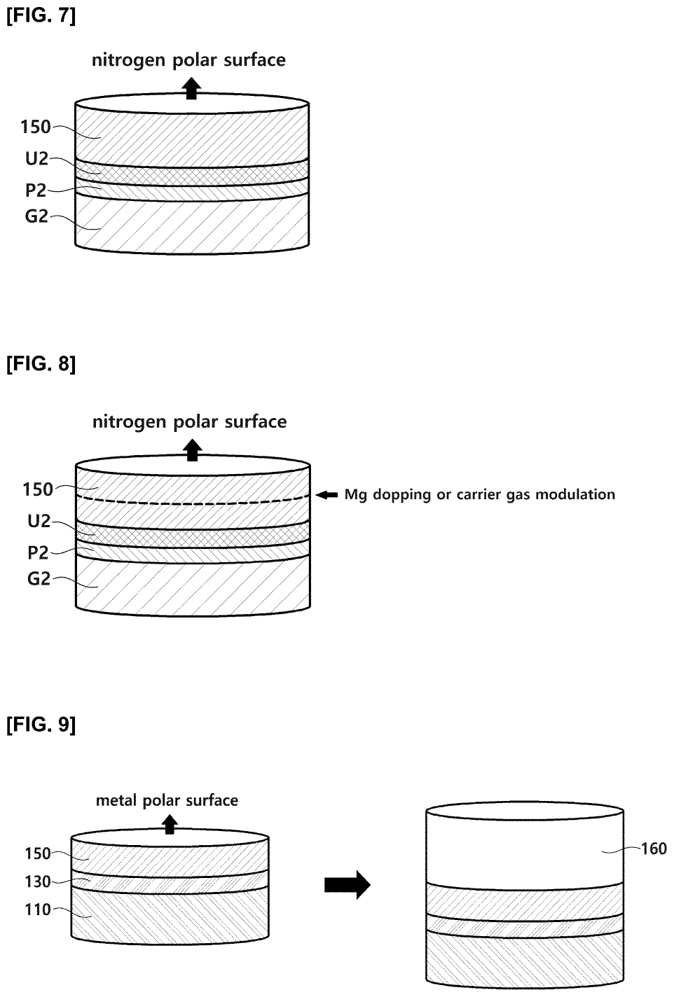

FIGS. 7 and 8 show that the seed layer 150 whose upper surface is a nitrogen polar surface is grown through the growing operation S210 of the method S200 of manufacturing a group III nitride semiconductor template according to the second embodiment of the present invention.

More specifically, the growing operation S210 includes preparing the initial growth substrate G2 on which the CMP process is performed, performing heat treatment on the initial growth substrate G2 at a high temperature of 1000° C. or higher in a hydrogen (H2) atmosphere, performing nitriding treatment on a surface of the growth substrate G2 at a high temperature of 1000° C. or higher in an ammonia atmosphere (NH3 and N2) to form an AlN layer P2 having a film or island shape in a thickness of less than 5 nm, depositing the GaN or AlN buffer layer U2 (or a nucleation layer) on the AlN layer P2 in a thickness of 50 nm or less at a high temperature of 850° C. or higher, and growing the seed layer 150 on the buffer layer U2 in a thickness of 2 μm or less.

As shown in FIG. 7, according to the growing operation S210, a structure in which the AlN layer P2, the GaN or AlN buffer layer U2, and the seed layer 150 are sequentially stacked is formed on the growth substrate G2, and the seed layer 150 having a nitrogen polar surface may be grown through the AlN layer P2 and the buffer layer U2 according to high-temperature nitriding treatment.

Meanwhile, as shown in FIG. 8, to reinforce the nitrogen polarity of the surface of the seed layer 150, Mg doping or carrier gas modulation may be performed on the seed layer 150 during growth.

Meanwhile, a channel through which gas generated during the process may move may be formed inside the seed layer 150 through an intentional patterning design.

Since the depositing operation S220 and the bonding operation S230 are the same as the above-described method of manufacturing a group III nitride semiconductor template according to the first embodiment of the present invention, overlapping descriptions thereof will be omitted.

The removing operation S240 is an operation of removing the initial growth substrate G2 to expose the metal polar surface of the seed layer 150.

The removing operation S240 includes removing the sapphire growth substrate G2 using an LLO process and specifically, includes irradiating a back surface of the optically transparent sapphire growth substrate G2 with a laser beam to separate the initial growth substrate G2 from the group III nitride semiconductor.

In this case, the removing operation S240 includes etching and removing both the AlN layer P2 and the buffer layer U2 that are formed in the growing operation S210 as well as the growth substrate G2 to expose the metal polar surface of the seed layer 150 transferred onto the final support substrate 110 and additionally etching and removing a region of the seed layer 150 on which Mg doping or carrier gas modulation is performed when the Mg doing or carrier gas modulation is performed on the seed layer 150 to expose the metal polar surface of the seed layer 150 transferred onto the final support substrate 110.

In this way, the device active layer 160 made of a high-quality group III nitride semiconductor may be re-grown on the seed layer 150 transferred onto the final support substrate 110 and having the exposed metal polar surface.

Meanwhile, in some cases, heat treatment may be performed at a high temperature of 400° C. or higher to increase the bonding strength of the bonding layer 130 after removing the sapphire growth substrate G2.

Since the re-growing operation is the same as the method of manufacturing a group III nitride semiconductor template according to the first embodiment of the present invention, overlapping descriptions thereof will be omitted.

As described above, although all the components constituting embodiments of the present invention are described as being combined or combined to operate as one, the present invention is not necessarily limited to these embodiments. That is, one or more of all the components may be combined to operate as one without departing from the scope of the purpose of the present invention.

In addition, the terms such as “comprise,” “constitute,” or “have” described above mean that the corresponding component can be included unless otherwise stated, and thus should be construed as further including another component rather than excluding another component. All terms including technical or scientific terms have the same meaning as commonly understood by those skilled in the art to which the present invention pertains unless defined otherwise. Commonly used terms, such as terms defined in dictionaries, should be interpreted as being consistent with the contextual meaning of the related art and are not interpreted in an ideal or excessively formal meaning unless explicitly defined herein.

In addition, the above description is merely an exemplary description of the technical spirit of the present invention, and those skilled in the art to which the present invention pertains will be able to variously modify and change the present invention without departing from the essential characteristics of the present invention.

Therefore, the embodiments disclosed in the present invention are not intended to limit the technical spirit of the present invention, but intended to describe the same, and the scope of the technical spirit of the present invention is not limited by these embodiments. The scope of the present invention should be construed by the appended claims, and all technical ideas within the equivalent scope should be construed as being included in the scope of the present invention.

1. A method of manufacturing a group III nitride semiconductor template, the method comprising:
a growing operation of growing a seed layer whose upper surface is a nitrogen polar surface on a growth substrate;
a depositing operation of depositing a protective layer on the seed layer;
a bonding operation of bonding the protective layer to a support substrate through a bonding layer; and
a removing operation of removing the growth substrate to expose a metal polar surface of the seed layer.

2. The method of claim 1, wherein the growth substrate is a silicon (Si) substrate.

3. The method of claim 2, wherein the growing operation includes:
performing high-temperature heat treatment on the growth substrate in a hydrogen atmosphere;
performing high-temperature nitriding treatment on a surface of the growth substrate in an ammonia atmosphere to form an SiN layer;
depositing a buffer layer on the SiN layer;
growing a compressive stress introduction layer on the buffer layer; and
growing a seed layer having a nitrogen polar surface on the compressive stress introduction layer.

4. The method of claim 3, wherein the removing operation includes removing the growth substrate, the SiN layer, the buffer layer, and the compressive stress introduction layer to expose the metal polar surface of the seed layer.

5. The method of claim 3, wherein Mg doping or carrier gas modulation is performed on at least one of the compressive stress introduction layer and the seed layer during growth.

6. The method of claim 5, wherein the removing operation includes removing the growth substrate, the SiN layer, the buffer layer, the compressive stress introduction layer, and a region of the seed layer on which the Mg doping or carrier gas modulation is performed to expose the metal polar surface of the seed layer.

7. The method of claim 1, wherein the growth substrate is a sapphire (Al₂O₃) substrate.

8. The method of claim 7, wherein the growing operation includes:
a first operation of performing high-temperature heat treatment on the growth substrate in a hydrogen atmosphere;
a second operation of performing high-temperature nitriding treatment on a surface of the growth substrate in an ammonia atmosphere to form an AlN layer;
a third operation of depositing a buffer layer on the AlN layer; and
a fourth operation of growing a seed layer having a nitrogen polar surface on the buffer layer.

9. The method of claim 8, wherein the removing operation includes removing the growth substrate, the AlN layer, and the buffer layer to expose the metal polar surface of the seed layer.

10. The method of claim 8, wherein Mg doping or carrier gas modulation is performed on the seed layer during growth.

11. The method of claim 10, wherein the removing operation includes removing the growth substrate, the AlN layer, the buffer layer, and a region of the seed layer on which the Mg doping or carrier gas modulation is performed to expose the metal polar surface of the seed layer.

12. The method of claim 1, wherein the depositing operation includes forming a reinforcement layer, which increases bonding strength and induces compressive stress, on the seed layer and then depositing the protective layer on the reinforcement layer.

13. The method of claim 1, wherein the bonding operation includes forming a reinforcement layer, which increases bonding strength and induces compressive stress, on the support substrate and then bonding the protective layer to the reinforcement layer through a bonding layer.

14. The method of claim 1, further comprising a re-growing operation of re-growing an device active layer on the exposed seed layer.
